(19) United States
(12) Patent Application Publication
(10) Pub. No.: US 2012/0319752 A1
(43) Pub. Date: Dec. 20, 2012

(54) LOOK-UP TABLES FOR DELAY CIRCUITRY IN FIELD PROGRAMMABLE GATE ARRAY (FPGA) CHIPSETS

(75) Inventors: Kenan Qu, Beijing (CN); Tonghai Gao, Beijing (CN)

(73) Assignee: TELEFONAKTIEBOLAGET LM ERICSSON(PUBL), Stockholm (SE)

(21) Appl. No.: 13/148,574

(22) PCT Filed: Jun. 17, 2011
(86) PCT No.: PCT/CN11/01007

§ 371 Date: Sep. 1, 2011

(51) Int. Cl. H03L 7/00; G06F 17/50

(52) U.S. Cl. 327/161; 716/117

(57) ABSTRACT

A method, new use for Look-Up Tables (LUTs), and a Field Programmable Gate Array (FPGA) chipset are provided for delaying data signals. The FPGA comprises an input and a set of LUTs operationally connected to and receiving from the interface a data signal and a clock signal. The set of LUTs delay the data signal by a delay so that a corresponding first delayed data signal output from the set of LUTs is so synchronized with the clock signal for appropriate sampling of the delayed data signal to be performed by the FPGA chipset. A process of manufacturing of the FPGA chipset comprises calculating a delay for delaying and synchronising the data signal with a clock signal to meet requirements of the chipset, calculating a number of LUTs for delaying the data signal, and implementing in a data path of the data signal the number of LUTs.

### TECHNICAL FIELD

The present invention relates to the field of Field Programmable Gate Array (FPGA) Chipsets.

### BACKGROUND

A Field-Programmable Gate Array (FPGA) is an integrated circuit designed to be configured by the customer or designer after manufacturing. The FPGA configuration may be specified using a hardware description language (HDL), similar to that used for an application-specific integrated circuit (ASIC). FPGAs can be used to implement any logical function that an ASIC could perform. The ability to update the functionality after shipping, partial re-configuration of the portion of the design and the low non-recurring engineering costs relative to an ASIC design (notwithstanding the generally higher unit cost), offer advantages for many applications. FPGAs contain programmable logic components called “logic blocks”, and a hierarchy of reconfigurable interconnects that allow the blocks to be “wired together” somewhat like many (changeable) logic gates that can be inter-wired in different configurations. Logic blocks can be configured to perform complex combinational functions, or merely simple logic gates like AND and XOR. In most FPGAs, the logic blocks also include memory elements, which may be simple flip-flops or more complete blocks of memory. FPGA carries digital ones and zeros on its internal programmable interconnect fabric. Applications of FPGAs include digital signal processing, software-defined radio, aerospace and defense systems, ASIC prototyping, medical imaging, computer vision, speech recognition, cryptography, bioinformatics, computer hardware emulation, radio astronomy, metal detection and a growing range of other areas.

Reference is now made to FIG. 1 (Prior Art) that shows a high level exemplary diagram of a prior art implementation of an FPGA unit 104. The FPGA unit is to receive a clock signal 106 and a data signal 108 from a memory unit 100. In many instances, a delay unit 102 is required in order to adjust the phase of the data signal 108 versus the phase of the clock signal 106 (shown as DQS in FIG. 1) in order to meet the requirements of the FPGA unit. The delay unit 102 acts, for example, to delay the phase of the data signal 108 and to output a delayed data signal 112 for input in the FPGA unit 104, whose phase is adjusted versus the clock's phase to meet the FPGA chipset's requirements. Therefore, the purpose of the delay unit 102 is to adjust the phase of a data signal versus the clock signal's (possibly not necessarily exactly as graphically shown in the exemplary FIG. 1) so that a proper reading and sampling of the data signal can be made by the FPGA unit's processing unit 118 (also called a register unit). While it is understood that the delay unit 102 may also act to slightly delay the clock signal, e.g. because of delays induced by the wires and circuitry of the unit 102, such delay is minimal and is thus not considered in the exemplary illustration of FIG. 2. Conclusively, according to this prior art implementation, the delay unit 102 is implemented in-between the memory unit 100 (e.g. a DRAM unit) and the FPGA chipset 104 in order to e.g. shift the phase of the data signal 108 by a certain delay value. However, this approach of using a delay unit 102 that is external to the FPGA chipset 104 has several disadvantages. First, the delay unit 102 needs extra space on the printed circuit board (PCB), and therefore such a layout is both more expensive and harder to design. Second, the RC (resistor-capacitor) parameter adjustment of such circuitry is also more complicated (since the delay value depends on the resistor value and the capacitor value, which are also related to signal quality such as noise, edge time etc).

Reference is now further made to FIG. 2 (Prior Art), which shows a high level illustration of another prior art implementation where an internal dedicated delay unit 102’ is used and implemented within an FPGA unit 104′ for the adjustment of the data signal phase. In this implementation, the memory unit 100 issues the same clock signal 106 (also shown as DQS in FIG. 2) and data signal 108 as previously described in relation to FIG. 1). In order to adjust the data and the clock signal's to properly meet the FPGA unit's requirements, an internal delay unit 102′ is inserted inside the FPGA unit 104′. The delay unit 102′ receives the clock signal 106 and the data signal 108 and delays the data signal by a certain delay value, therefore producing a delayed data signal 112 that meets the requirements of the FPGA unit 118 (note that the phase alignment may not necessarily be as graphically shown in FIG. 1). While it is understood that the delay unit 102′ may also act to slightly delay the dock signal, e.g. because of delays induced by the wires and circuitry of the unit 102′, such delay is minimal and is thus not considered in the exemplary illustration of FIG. 2. The delayed data signal 112 is then input in the processing unit 118 of the FPGA, so that proper reading and processing (e.g. sampling) of the data signal can be accomplished. The type of implementation shown in FIG. 2 is essentially applicable to high-end FPGA chipsets where dedicated delays units are implemented within the FPGA chipsets for data signal phase adjustment. In such implementations, a designer can directly use the delay unit in order to control the delay value of the data signal. However, because of the cost of the internal delay unit, only high-end series of newer FPGA chipsets contain the dedicate delay cell. Moreover, the delay cells of some FPGA chipsets may need a special high frequency of up to 200 MHz in order to operate properly. In many designs, this clock speed is not needed in absence of the delay cell, and therefore such an implementation generally renders the FPGA unit more expensive.

Accordingly, it should be readily appreciated that in order to overcome the deficiencies and shortcomings of the existing solutions, it would be advantageous to have an efficient, inexpensive and simple solution for synchronizing the data signal with the clock signal in FPGA units.

### SUMMARY

With the present invention it becomes possible to avoid the necessity of having dedicated delay circuits that are typically used in FPGA chipsets, and achieve the proper adjustment of the phase of the one or more data signals using one ore more proper sets of look-up tables inside the FPGA chipset. This saves space on the PCB (compared for example to the external delay circuitry of the prior art) or inside the FPGA chipset (compared to the internal FPGA delay circuit). Likewise, since the invention proposes the use of LUTs for use as a delay circuit, and since LUTs are many times needed anyhow inside an FPGA chipset, the invention allows also for reducing the costs associated with the FPGA chipsets manufacturing.

In one embodiment, the present invention is a Field Programmable Gate Array (FPGA) chipset, comprising an input interface and a set of one or more look-up tables (LUTs) operationally connected to the input interface and receiving from the input interface a data signal and a clock signal. The set of LUTs delay the data signal by a delay value so that a corresponding delayed data signal output from the set of LUTs is so synchronized with the clock signal for appropriate sampling of the first delayed data signal to be performed by a processing unit of the FPGA chipset.

In another embodiment, the invention is a method for signal delay in an FPGA chipset, the method starting by receiving from an input interface of the FPGA chipset a data signal at a set of one or more look-up tables (LUTs) operationally connected to the input interface. The method then allows for the delaying, by the set of LUTs, the data signal by a delay value so that a corresponding first delayed data signal output from the first set of one or more LUTs is so synchronized with a clock signal for appropriate sampling of the first delayed data signal to be performed by a processing unit of the FPGA chipset.

In yet another embodiment, the invention is a process of manufacturing a FPGA chipset comprising a set of one or more LUTs used for delaying one or more data signals, the process comprising calculating a delay value for delaying a data signal for the data signal to be so synchronized with a clock signal that a relationship between phases of the data signal and the clock signal meets a hold time requirement and a setup time requirement of the FPGA chipset. The method further comprises calculating a first number of LUTs needed for delaying the data signal by the delay value, and implementing in a data path of the data signal the number of LUTs needed for delaying the first signal by the first delay value.

In yet another embodiment, the invention is a new use for a set of one ore more LUTS in an FPGA chipset, wherein the set of LUTs is used to delay a data signal by a delay value for synchronizing the data signal with a clock signal, wherein a relationship between phases of the data signal and the clock signal meets a hold time requirement and a setup time requirement of the FPGA chipset.

### BRIEF DESCRIPTION OF THE DRAWINGS

For a more detailed understanding of the invention, for further objects and advantages thereof, reference can now be made to the following description, taken in conjunction with the accompanying drawings, in which:

FIG. 1 (Prior Art) is a high level block diagram representative of a first prior art implementation of a delay circuitry connected to an FPGA unit;

FIG. 2 (Prior Art) is another prior art implementation of an internal delay unit implemented within the FPGA unit;

FIG. 3 is a high level block representation of an exemplary preferred embodiment of the invention.

FIG. 4.a is an exemplary high level representation of a preferred embodiment of the present invention related to a setup time requirement of an FPGA unit;

FIG. 4.b is an exemplary high level representation of a preferred embodiment of the present invention related to a hold time requirement of an FPGA unit;

FIG. 4.c is an exemplary high level representation of a preferred embodiment of the present invention related to both a hold time and setup time requirement of an FPGA unit;

FIG. 5 is an exemplary high level representation of a preferred embodiment of the present invention related to the use of a delay unit comprising one or more look-up tables;

FIG. 6 is an exemplary high level representation of a preferred embodiment of the present invention related to method for manufacturing of an FPGA chipset that includes a delay unit with one or more LUTs;

FIG. 7.a is an exemplary high level representation of a preferred embodiment of the present invention related to the calculation of a minimum delay time of a data signal sent to an FPGA chipset;

FIG. 7.b is an exemplary high level representation of a preferred embodiment of the present invention related to the calculation of a maximum delay time of a data signal sent to an FPGA chipset; and

FIG. 8 is an exemplary high level representation of a preferred embodiment of the present invention related to the use of multiple delay units for delaying multiple data signals in an FPGA chipset.

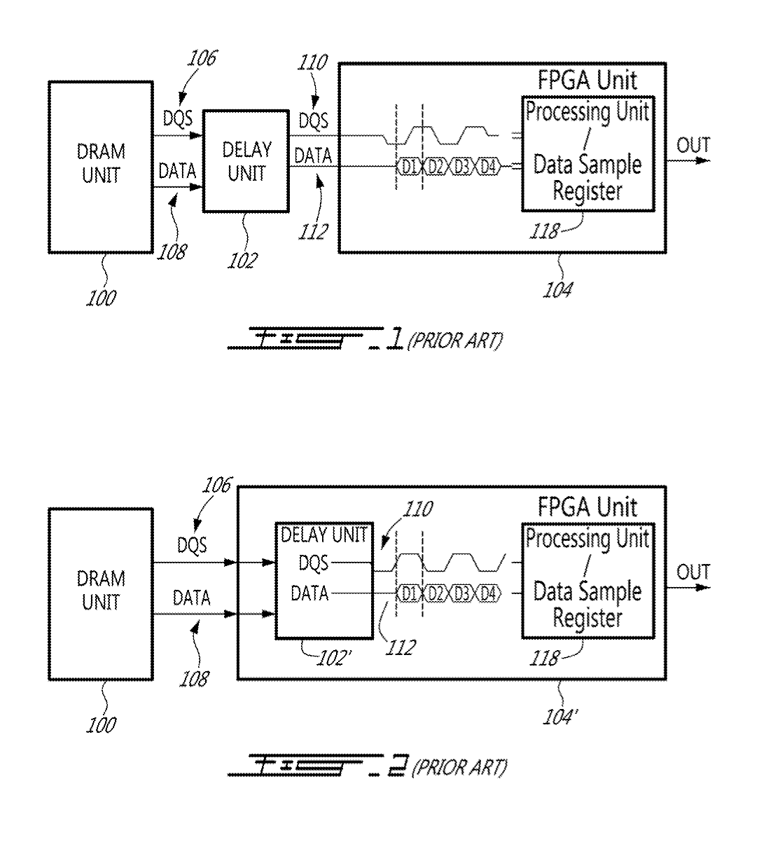

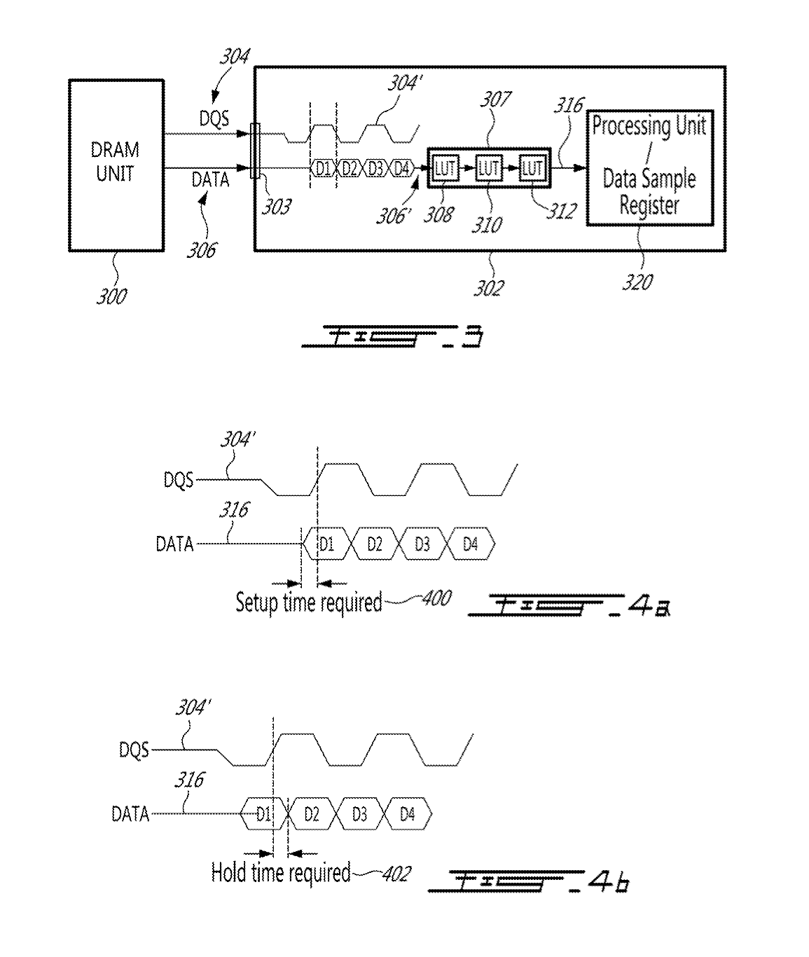

### DETAILED DESCRIPTION

The innovative teachings of the present invention will be described with particular reference to various exemplary embodiments. However, it should be understood that this class of embodiments provides only a few examples of the many advantageous uses of the innovative teachings of the invention. In general, statements made in the specification of the present application do not necessarily limit any of the various claimed aspects of the present invention. Moreover, some statements may apply to some inventive features but not to others. In the drawings, like or similar elements are designated with identical reference numerals throughout the several views.

When the FPGA chipset samples a data signal, the phase relationship of the data signal and corresponding clock signal must meet a series of requirements imposed by the FPGA chipset itself. If the data signal phase is not adjusted and properly synchronized in a certain way with the clock signal's phase received from the memory unit, then the FPGA chipset requirements are not met and proper reading and processing of the data signal can not be performed.

Embodiments of the present invention ensure that the phase relationship between data signal(s) and clock signals meets the requirements of FPGA chipset in an efficient and inexpensive way. In some embodiments, the present invention provides for a new FPGA chipset implementation that uses look-up tables (LUTs) in order to delay one or more data signals that need to be synchronized with a clock signal before hitting the processing unit (also called the register) of the FPGA chipset. Moreover, the preferred embodiment of the present invention further provides a method of delaying one or more data signals by using a set (or more) of one or more LUTs in order to delay the data signal and synchronize its phase with a clock signal before both are input in the processing unit or a register of the FPGA chipset. In some embodiments, the invention provides for a less expensive FPGA chipset, where LUTs are used in order to perform actions previously performed in the prior art by a dedicated delay circuitry that was expensive and hard to implement in the limited space of the FPGA chipset and/or of the PCB. Therefore, the present invention allows, for example, for PCB space and costs to be saved by making the system design simpler. Likewise, embodiments of the present invention may be used and implemented with many types of DRAM-to-FPGA interfaces including but being not limited to SD-RAM, DDR, or QDR interfaces. Finally, embodiments of the present invention may be implemented for various types and numbers of data signals and/or clock signals that need to be input in an FPGA chipset. For example, in some embodiments of the invention, different sets of look-up tables can be used in the data paths of the various data signals or clock signals to provide for an adjusted and personalized type of delay for each such data signal.

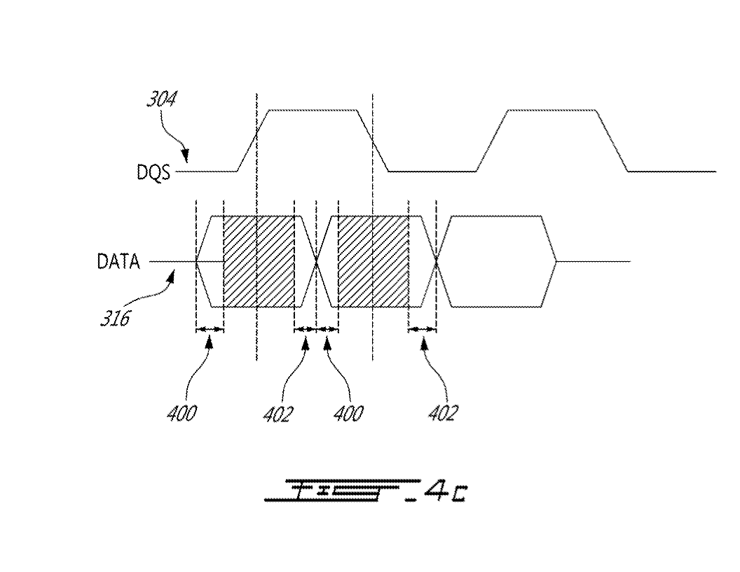

Reference is now made to FIG. 3 that shows a preferred embodiment of the present invention implemented in a FPGA chipset 302. Shown in FIG. 3 is a memory unit 300 connected to an FPGA chipset 302. The later comprises an input interface 303 operationally connected to a set 307 of Look-Up Tables 308, 310, and 312, itself further connected to a processing unit/sampling register 320. The memory 300 sends a clock signal 304 and a first data signal 306 to the FPGA chipset 302. The signals 304 and 306 are received at the input interface 303 of the chipset 302 and corresponding signals 304′ and 306′ are further sent from the input interface towards the processing unit/sampling register 320 of the FPGA chipset 302. Signals 304′ and 306′ correspond to signals 304 and 306 once received and possibly slightly delayed by the input interface 303 (e.g. because of the internal wires and circuitry). When the clock signal 306 and data signal 304 are sent from the memory unit 300 and received at the FPGA chipset 302, their phase may be aligned as shown in FIG. 3, i.e. in phase sync (the raising/active edge of the clock signal 304′ corresponding, in time, to the beginning of the data signal blocks). However, this phase alignment between the clock signal 304′ and the data signal 306′ does not meet the FPGA chipset's sampling requirement (as each FPGA chipset has particular requirements on the synchronization required between the data signal and the clock signal, for a proper reading and processing of the data signal to take place). Therefore, it is assumed in the present exemplary scenario, that the data signal 306′ needs to be delayed by a certain delay value (measured, for example in nano-seconds) in order to meet the requirements of the FPGA chipset 302. For this purpose, according to a preferred embodiment of the present invention, a set 307 of look-up tables (LUTs) 308, 310, 312, is provided in the data path of the data signal 306′ in order to delay the signal by a certain delay value, so that an adjusted and delayed data signal 316 is output from the set of LUTs 307. The delayed data signal 316 is assumed to have a signal phase in relation with the clock signal 304′ that meets the FPGA chipset's requirements, so that both the delayed data signal 316 and the clock signal 304′ can be input in the processing unit 320 of the FPGA chipset 302 for proper further processing.

The FPGA chipset's sampling requirement usually consists of two (2) parts. First, a set-up time requirement is needed for the FPGA unit 302 (and more particularly the processing unit 320) to be able to properly read and sample the data signal.

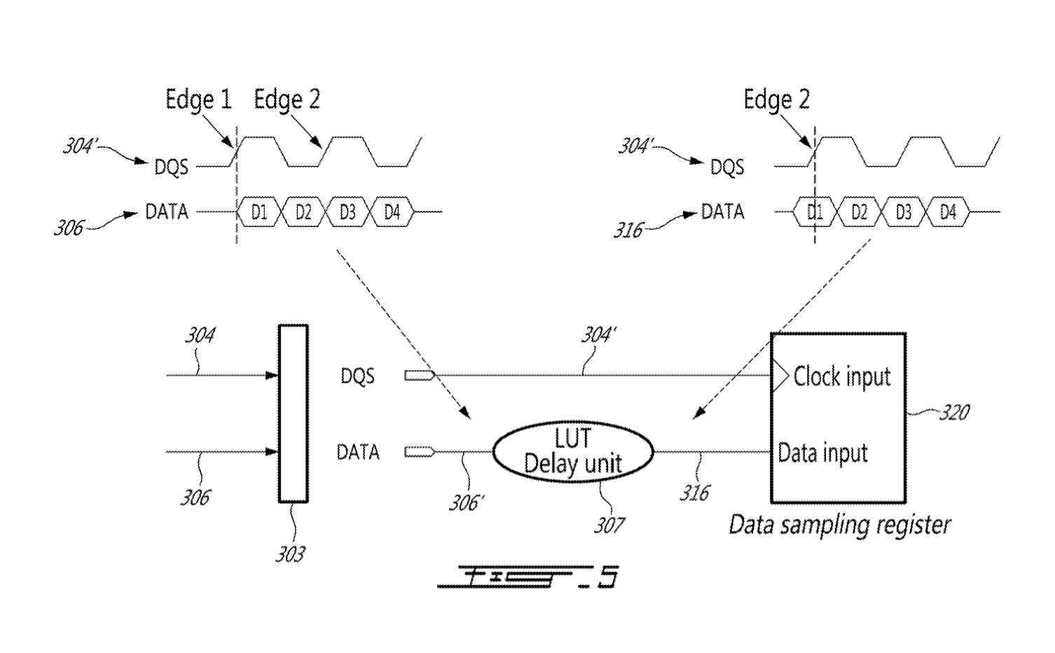

Reference is now made to FIG. 4.a that shows an example of set-up time requirement 400 calculated for an exemplary clock signal 304′ and an exemplary data signal 316. The set-up time is defined as the minimum amount of time before the clock signal's active (raising) edge the data signal must be stable for the FPGA unit to be capable to properly read the data signal. Any violation of this minimum required time causes incorrect data to be captured and is known as set-up violation. In FIG. 4.a, the set-up time 400 is calculated from the beginning of the data block up to the raising edge of clock signal (DQS).

Second, the FPGA sampling requirement also comprises a hold time, defined as the minimum amount of time after the dock signal's active edge during which the data must be stable for a proper reading to take place, as exemplarily shown in FIG. 4.b. Shown in FIG. 4.b, is the exemplary clock signal 304′ and the same exemplary data signal 316′ in relation to the calculation of the hold time requirement 402. Any violation in this required time causes incorrect data to be captured and is known as a hold violation. The hold time 402 is calculated from the clock signal's (DQS) 304′ raising edge up to the end of the data block of the data signal 316.

When the FPGA chipset 302 samples a data signal by using a clock signal, the phase relationship of the data signal and the clock signal must meet both the setup time and the hold time requirement for proper sampling to take place. This means that the clock signal's raising edge must be at (substantially) the middle of the data signal blocks, and that the clock signal's falling edge must be at (substantially) the middle of the data signal blocks (since the FPGA uses both raising and falling edges to sample data).

Reference is now made to FIG. 4.c, which shows an exemplary phase relationship of a clock signal 304′ and of an adjusted and delayed data signal 316 that meets an FPGA chipset's sampling requirement in terms of both setup time 400 and hold time 402. If the clock signal's (DQS) edge falls in the shadowed regions of the data signal 316 of FIG. 4.c, then both the setup time 400 and hold time 402 requirements are met.

Such a data signal 316 may be output by the set 307 of LUT(s) of the FPGA chipset 302 and may be input into the processing unit 320 for proper sampling and further processing.

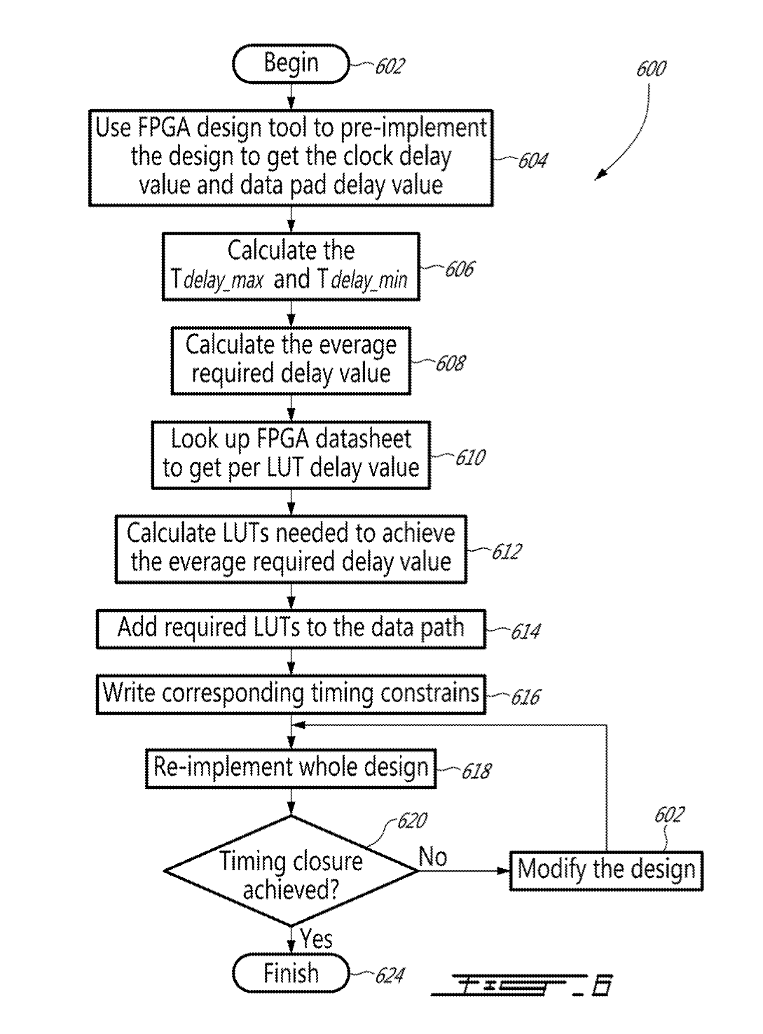

Reference is now made jointly to FIG. 3 and to FIG. 5, which shows an exemplary illustration of a set 307 of LUTs used as a delay unit in an FPGA chipset 302 according to the preferred embodiment of the present invention. FIG. 5 shows a clock signal 304′ and the data signal 306′ received in the FPGA chipset via the input interface 303, once they have transited through the input interface 303. The signals 304′ and 306′ correspond to the signal 304 and 306 with some induced delays, e.g. by the interface 303. Before the data signal 306′ hits the delay unit 307, the phase of the data signal 306 is not properly aligned with the phase of the clock signal 304′ for the hold time and the setup time requirements to be met. The data signal 306′ is therefore passed through the delay unit 307 containing one or more LUTs, so that it is delayed by a certain delay value. The delay value is selected so that at the output of the LUT delay unit 307, a delayed data signal 316 is generated and has a signal phase properly aligned with the one of the clock signal for meeting those requirements. Then, the clock signal 304′ and the delayed data signal 316, which phase relationship now meet the setup time requirement and the hold time requirement, are both input in the data sampling register 320 for further processing. More particularly, the delay induced by the LUT delay unit 307 to the data signal 306′ adjusts the phase of the data signal 316 with the clock signal's so that the clock signal's raising edge is at the middle of, for example, the data signal's D1 block, and further that the falling edge of the clock signal is aligned with the middle of the data signal's D2 data block. In this manner, both the setup time and hold time requirements of the FPGA chipset are met. FIG. 5 shows that the LUT delay unit 307 delays the data signal so that the raising edge 2 of the clock signal DQS can be at the middle of the data signal's D1 block.

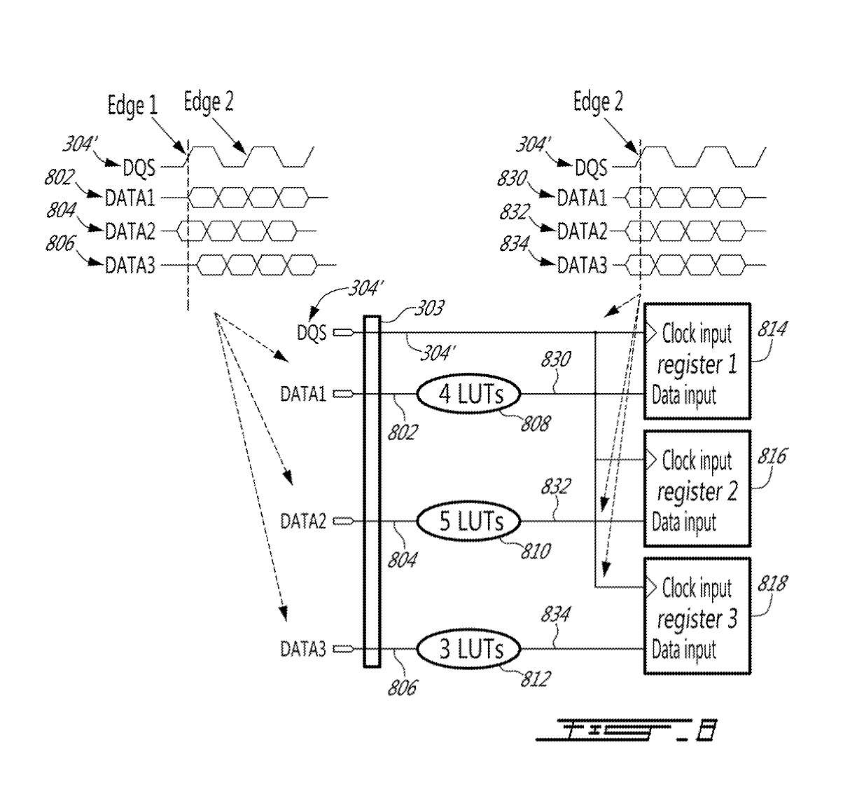

FIGS. 7.a and 7.b show more detailed embodiments of the present invention related to the calculation of a delay value for delaying a data signal using a delay unit 307 comprising one or more LUTs. Such a delay value may be calculated as a value that is in between, or the average, or substantially the average of, a minimum delay value and a maximum delay value, calculated as described hereinbelow.

Reference is now made particularly to FIG. 7.a, which shows a more detailed representation of a preferred embodiment of the invention related to the manner of calculating a minimum delay value for delaying a data signal in an FPGA chipset so as the phase relationship of that data signal and its corresponding clock signal meet the FPGA chipset's setup time and hold time requirement. FIG. 7.a shows the following signals used for the calculation of the minimum delay value:
DQS_DDR_Output is the clock signal 304 output by the memory unit 300,
DATA_DDR_Output is the data signal 306 output by the memory unit 300,
DQS_FPGA_Input is a slightly delayed clock signal 304′ (vs signal 304) once it enters the FPGA chipset 302, e.g. after being received by the input interface 303. The delay of the DQS_FPGA_Input vs signal 304 may be due to the wires and other circuitry of the interface 303.
DATA_FPGA_Input is a slightly delayed data signal 306′ (vs signal 306) once it enters the FPGA chipset 302, e.g. after being received by the input interface 303. The delay of the DATA_FPGA_Input signal 306′ (vs the signal 306) may be due to the wires and circuitry of the interface 303.
   and further shows the following parameters used for the calculation of the minimum delay values:
DCLK (delayed clock value): all the signals are delayed when entering the FPGA chipset; DCLK 304′ is the delayed value of the clock signal (DOS) 304. The accurate DCLK delay value can be obtained from an FPGA design tool or specification. In FIG. 7.a, the DCLK is computed from the falling edge of DQS_DDR output 304 to the same falling edge of DQS_FPGA input 304′.
Ddata_pad (delayed data signal value): all signals are delayed when entering the FPGA chipset; Ddata_pad is the delayed value of the data signal once it enters the FPGA chipset 302 but before being delayed by the LUT delay unit 307. The accurate delay value of Ddata_pad can be provided also by an FPGA design tool. In FIG. 7.a the Ddata_pad is calculated, for example, from the beginning of DATA_DDR output D2 block to the beginning of DATA_FPGA input D2 block (using the D2 data block is convenient for formula calculation and illustration purposes).
Thold_min: is the hold time, as previously described. It is defined as the minimum amount of time after the clock's active edge during which the data signal must be stable for a proper reading to take place. Any violation in this required time causes incorrect data to be captured and is known as hold violation. Thold_min can be obtained from either an FPGA chipset's datasheet or from a design tool.
Tdelay_Min: is the minimal delay value that must be induced to the data signal 306′ by the LUT delay unit 307 for insuring that the phase relationship of the so-delayed data signal 316 and the delayed clock signal 304′ meet the FPGA chipset's requirements (e.g. that the data can be sampled correctly). It means that the value from raising edge of dock to the end of the data block must be superior to the Thold_min. Tdelay_min can be calculated as follows:

Tdelay_min=½ Tcycle−Ddata_pad+Dclk+Thold_min
where TCycle is the period of the DQS_FPGA_input.

Reference is now made to FIG. 7.b, which shows a preferred embodiment of the invention related to the calculation of a maximum delay value to be used for delaying a data signal to be input in an FPGA chipset so as the phase relationship of that data signal and the corresponding clock. signal meet the FPGA chipset's setup time and hold time requirement. FIG. 7.b shows the same signals and parameters as previously detailed in relation with FIG. 7.a, except for:
Tsetup_min: is the setup time, as previously described. It is defined as the minimum amount of time before the clock signal's active (raising) edge the data signal must be stable for the FPGA unit to be capable to properly read (sample) the data signal. Any violation in this required setup time causes incorrect data to be captured and is known as setup time violation. Tsetup_min can be obtained from either an FPGA chipset's datasheet or from a design tool.
Tdelay_Max: is the maximum delay value that must be induced to the data signal 306″ by the LUT delay unit 307 for insuring that the phase relationship of the so-delayed data signal 316 and the delayed clock signal 304′ meets the FPGA chipset's requirements (e.g. that the data can be sampled correctly). Tdelay_max can be calculated as follows:

Tdelay_max=Tcycle−Ddata_pad+Dclk−Tsetup_min
where TCycle is the period of the DQS_FPGA_input.

According to one of the preferred embodiments of the invention, once the values of the minimum delay value Tdelay_Min and of the maximum delay value Tdelay_max are calculated as described hereinabove, the LUT delay unit 317 can be configured to delay the data signal 306′ by a delay value comprised in between these two values, so that the FPGA chipset's requirements in terms of hold time and setup time are both met. In a particular embodiment, an average of the Tdelay_max and Tdelay_min is calculated and the LUT delay unit 317 is configured so as to induce to the data signal 306′ a delay that corresponds to the average of Tdelay_max and Tdelay_min. Other delays may also be computed as long as they meet the requirements of the minimum and maximum delays values.

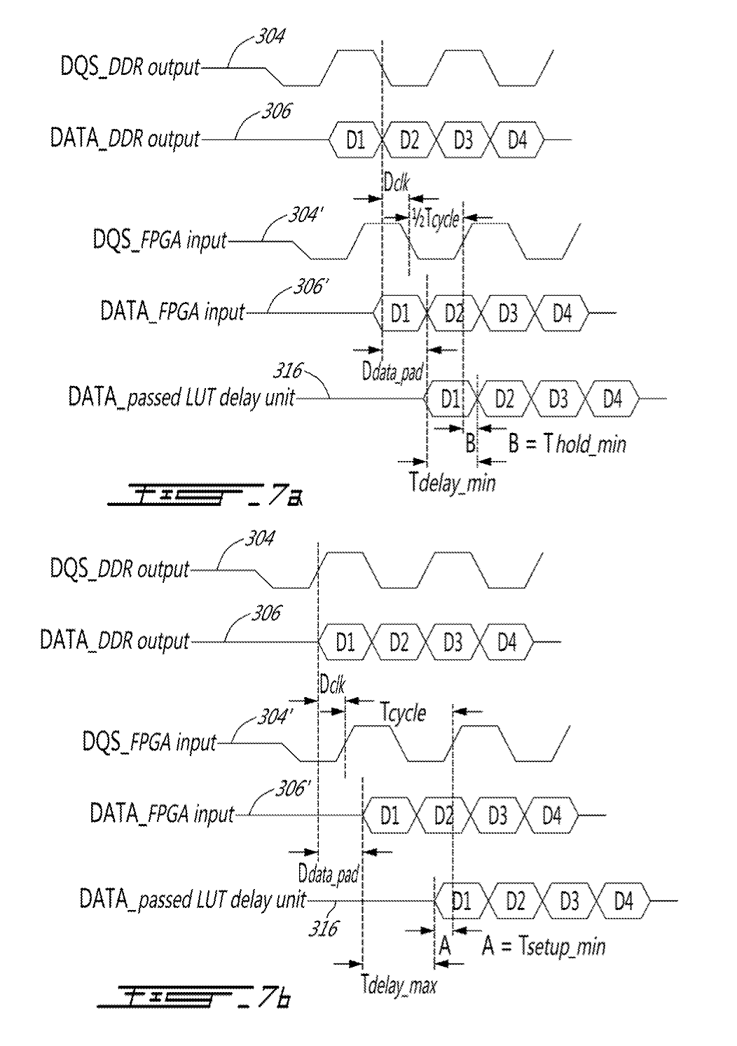

Reference is now made to FIG. 6, which is an exemplary flow chart diagram of a preferred embodiment of the present invention related to a process of manufacturing an FPGA chipset comprising a set of one or more look-up tables used for delaying a data signal (or more data signals) so that the phase relationship between the data signal and its corresponding clock signal meets specified requirements of the FPGA chipset. According to this exemplary preferred embodiment of the present invention, the proposed process of manufacturing comprises calculating a first delay value for delaying a first data signal for the data signal to be synchronized with the clock signal, then calculating a first number of look-up tables needed for delaying the first data signal by the delayed value, and implementing in a data path of the first data signal the first number of look-up tables needed for delaying the first signal by the first delayed value. In more details, the process 600 starts in action 602, and in action 604 an FPGA design tool is for example used to pre-implement a proposed design of the FPGA chipset in order to obtain a clock delay value and a data pad delay value. Further, in action 606, the process allows for the calculation of the maximum delay value Tdelay_max and the minimum delay value Tdelay_min, for example as described hereinbefore in relation to FIGS. 7.a and 7.b. In action 608, a data signal delay value is calculated, such as for example by averaging the maximum delay value Tdelay_max and the minimum delay value Tdelay_min, as calculated in action 606. In action 610, the delay value of each look-up table that is considered for being implemented in the FPGA chipset is extracted, such as for example from a specification database or a data sheet related to the LUT. In action 612, the process calculates what types and how may look-up tables are needed to achieve the required delay value as calculated in action 608. Action 612 may include also determining, for example, the topology of the LUTs connections, i.e. how the determined number and type of LUTs should be connected together in order to produce, globally, the desired delay for the data signal. In action 614, the proper types and number of look-up tables are added in the data signal's path in order to obtain the required delay value. Further, in action 616, the corresponding time constraints are saved, such as for example saving timing constrains generated by an FPGA design tool or directly write timing constrains in a constraint file (e.g. a file similar to text file). The usage of the timing constrains is for defining how many LUTs are to be used, locate the LUTs delay unit in FPGA, calculating the delay value of the entire LUTs delay unit, the connection of data signals, LUTs delay unit, and sampling register and so on). Further, in action 618, the entire so-obtained design is implemented, using, for example, the same FPGA design tool. In action 620, verification is made as to whether or not the timing closure values (i.e. both Tₛₑₜᵤₚ_{_{—}}ₘᵢₙ and T_{hold}_{_{—}}ₘᵢₙ requirement) are met, and in the affirmative, the process is finished in action 624. If it is rather determined in action 620 that the closure values are not achieved, then in action 622 the design of the FPGA chipset in terms of, for example the number or the layout of the look-up tables can be modified, and the process returns to action 618 for the whole design to be updated and implemented again, and for the verifications of action 620 to be made again. The actions 618, 620, and 622 may be repeated, for example, until a proper design is found for the FPGA chipset, where the setup time and the hold time of the FPGA chipset are met.

Reference is now made to FIG. 8, which shows another exemplary preferred embodiment of the present invention, where an FPGA chipset handles multiple data signals. The plurality of data signals are received at the input interface 303 of the FPGA chipset 302 and are delayed using various sets of LUTs for each data signal to meet the FPGA chipset's requirements (in terms of hold time and setup time, as described hereinbefore). According to the present exemplary preferred embodiment of the invention a first data signal 802, a second data signal 804, a third data signal 806 and a clock signal 304′ are shown after having been received at, and having transited the FPGA chipset's input interface 303. The phase of the data signals 802 to 806 need to be adjusted and properly synchronized with the clock signal 304′ before being input in the corresponding registers 814, 816, and 818 of the FPGA chipset for proper reading and processing. For this purpose, three (3) sets 808, 810, and 812 of LUTs are provided in order to properly adjust the phase of each data signal in accordance with the requirements of the FPGA chipset 302. For example, the first data signal 802 is input into a set 808 of four (4) look-up tables which delays the first data signal 802 by a first delay value in order to produce a delayed data signal 830, which is further input into the register 814 for reading and processing, along with the clock signal 304′. Likewise, the second data signal 804 is input into a set 810 of five (5) look-up tables 810 in order to be delayed, so that an adjusted data signal 832 is produced and further input into the register 816, along with the clock signal 304′, for further processing. A similar treatment is applied to the third data signal 806, which is input into a set 812 of three (3) look-up tables 812 before being delayed so that a delayed data signal 834 is created, that is input for processing into the register 818 along the clock signal 304′. The number of look-up tables necessitated by each set 808, 810 and 812 is dependent on the phase delay that needs to be inflicted to each one of the data signals 802, 804 and 806. The delay of each signal and the design of the entire FPGA chipset 302 may be calculated and performed as described hereinbefore and shown in relation to FIGS. 6 and 7.

Therefore, with the present invention it becomes possible to avoid the necessity of having dedicated delay circuits that are typically used in FPGA chipsets, and achieve the proper adjustment of the phase of the one or more data signals using one ore more proper sets of look-up tables, inside the FPGA chipset. This saves space on the PCB (compared for example to the external delay circuitry of the prior art) or inside the FPGA chipset (compared to the internal FPGA delay circuit). Likewise, since the invention proposes the use of LUTs for use as a delay circuit, and since LUTs are needed anyhow inside an FPGA chipset in many instances for other processing purposes, the invention allows also for reducing the costs associated with the FPGA chipsets manufacturing.

Based upon the foregoing, it should now be apparent to those of ordinary skills in the art that the present invention provides an advantageous solution for delaying and adjusting a data signal phase with the phase of a clock signal for meeting the requirements of an FPGA chipset. It is believed that the operation and construction of the present invention will be apparent from the foregoing description. While the method and system shown and described have been characterized as being preferred, it will be readily apparent that various changes and modifications could be made therein without departing from the scope of the invention as defined by the claims set forth hereinbelow.

Although several preferred embodiments of the method and system of the present invention have been illustrated in the accompanying Drawings and described in the foregoing Detailed Description, it will be understood that the invention is not limited to the embodiments disclosed, but is capable of numerous rearrangements, modifications and substitutions as set forth and defined by the following claims.

1. A Field Programmable Gate Array (FPGA) chipset, comprising:
an input interface; and
a first set of one or more look-up tables (LUTs) operationally connected to the input interface and receiving from the input interface a first data signal and a clock signal, the first set of one or more LUTs delaying the first data signal by a first delay value so that a corresponding first delayed data signal output from the first set of one or more LUTs is so synchronized with the clock signal for appropriate sampling of the first delayed data signal to be performed by a processing unit of the FPGA chipset.

2. The FPGA chipset of claim 1, wherein the first delay value is selected to delay the first data signal so that a clock signal's raising edge falls in a centre of a data block of the first data signal, and so that a clock signal's falling edge falls in the centre of another block of the data signal.

3. The FPGA chipset of claim 1, wherein the first delay value is selected to delay and synchronize the first data signal with the clock signal so that a setup time value and a hold time value of the FPGA chipset are met.

4. The FPGA chipset of claim 1, wherein the input interface receives the clock signal and the first data signal from an external memory via the input interface.

5. The FPGA chipset of claim 4, wherein the external memory is a memory unit selected from the group of memory units consisting of a Dynamic Random-Access Memory (DRAM), a Synchronous Dynamic Random Access Memory (SDRAM), and a Double Data Rate Synchronous Dynamic Random Access Memory (DR SDRAM).

6. The FPGA chipset of claim 1, further comprising:
a second set of one or more look-up tables (LUTs) operationally connected to the input interface and receiving from the input interface the second data signal, the second set of one or more LUTs delaying the second data signal by a second delay value so that a corresponding second delayed data signal output of the second set of one or more LUTs are so synchronized with the clock signal for appropriate sampling of the second delayed data signal to be performed by the processing unit of the FPGA chipset.

7. The FPGA chipset of claim 1, wherein the processing unit comprises a register unit, wherein the first delayed data signal and the clock signal are further input in the register unit of the FPGA chipset.

8. The FPGA chipset of claim 1, wherein the first delay value is a value selected between a minimum delay value and a maximum delay value.

9. The FPGA chipset of claim 8, wherein the first delay value is calculated as an average between the minimum delay value and the maximum delay value.

10. The FPGA chipset of claim 4, wherein the first delay value and the second delay value are different.

11. A method for data signal delay in a Field Programmable Gate Array (FPGA) chipset, the method comprising:
receiving from an input interface of the FPGA chipset a first data signal at a first set of one or more look-up tables (LUTs) operationally connected to the input interface; and
delaying, by the first set of one or more LUTs, the first data signal by a first delay value so that a corresponding first delayed data signal output from the first set of one or more LUTs is so synchronized with a clock signal for appropriate sampling of the first delayed data signal to be performed by a processing unit of the FPGA chipset.

12. The method of claim 11, wherein the first delay value is selected to delay the first data signal so that a clock signal's raising edge falls in a centre of a data block of the first data signal, and so that a clock signal's falling edge falls in the centre of another block of the data signal.

13. The method of claim 11, wherein the first delay value is selected to delay and synchronize the first data signal with the clock signal so that a setup time requirement and a hold time requirement of the FPGA chipset are met.

14. The method of claim 11, wherein the input interface receives the clock signal and the first data signal from an external memory.

15. The method of claim 11, wherein the external memory is a memory unit selected from the group of memory units consisting of a Dynamic Random-Access Memory (DRAM), a Synchronous Dynamic Random Access Memory (SDRAM), and a Double Data Rate Synchronous Dynamic Random Access Memory (DR SDRAM).

16. The method of claim 11, further comprising:
receiving a second data signal at the input interface of the FPGA chipset;
receiving from the input interface the second data signal at a second set of one or more look-up tables (LUTs) operationally connected to the input interface; and
delaying, by the second set of one or more LUTs, the second data signal by a second delay value so that a corresponding second delayed data signal output of the second set of one or more LUTs is so synchronized with the clock signal for appropriate sampling of the second delayed data signal to be performed by a processing unit of the FPGA chipset.

17. The method of claim 1, further comprising the step of:
sending the first delayed data signal and the clock signal to a register unit of the FPGA chipset.

18. The method of claim 1, wherein the first delay value is a value selected between a minimum delay value and a maximum delay value.

19. The method of claim 14, wherein the first delay value is calculated as an average between the minimum delay value and the maximum delay value.

20. The method of claim 12, wherein the first delay value and the second delay value are different.

21. A process of manufacturing a Field Programmable Gate Array (FPGA) chipset comprising a set of one or more Look-Up Tables (LUTs) used for delaying one or more data signals, the process comprising:
calculating a first delay value for delaying a first data signal, for the first data signal to be so synchronized with a clock signal that a relationship between phases of the data signal and the clock signal meets a hold time requirement and a setup time requirement of the FPGA chipset;
calculating a first number of LUTs needed for delaying the first data signal by the delay value; and
implementing in a data path of the first data signal the first number of LUTs needed for delaying the first signal by the first delay value.

22. The process of manufacturing the FPGA chipset of claim 21, wherein the step of calculating the delay value further comprises the steps of:
calculating a maximum delay value and a minimum delay value;
selecting the delay value for delaying the first data signal between the maximum delay value and the minimum delay value.

23. The process of manufacturing the FPGA chipset of claim 21, further comprising the steps of:
calculating a second delay value for delaying a second signal, for the second signal to be synchronized with the clock signal;
calculating a second number of LUTs needed for delaying the second signal by the delay value; and
implementing in a data path of the second signal the first number of LUTs needed for delaying the second signal by the second delay value.

24. A new use for a set of one ore more Look-Up Tables (LUTs) in a Field Programmable Gate Array (FPGA) chipset, wherein the set of LUTs is used to delay a data signal by a delay value for so synchronizing the data signal with a clock signal, wherein a relationship between phases of the data signal and the clock signal meet a hold time requirement and a setup time requirement of the FPGA chipset.
